(19) United States
(12) Patent Application Publication
(10) Pub. No.: US 2009/0025972 A1
(43) Pub. Date: Jan. 29, 2009

(54) Solder Mounting Structure, Manufacturing Method and Apparatus of the Solder Mounting Structure, Electronic Apparatus, and Wiring Board

(75) Inventors: Katsuitsu Nishida, Soraku-gu Kyoto (JP); Kazuo Kinoshita, Fukuyama-shi Hiroshima (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 12/087,083

(22) PCT Filed: Nov. 20, 2006
(86) PCT No.: PCT/JP2006/323093

§ 371 Date: Jun. 25, 2008

(30) Foreign Application Priority Data
Dec. 27, 2005 (JP) 2005-376473

(51) Int. Cl. H05K 1/11; G03B 17/00; B23K 31/02

(52) U.S. Cl. 174/263; 396/439; 219/148

(57) ABSTRACT

A camera module structure (100) of the present invention is arranged such that a heat-sensitive camera module (2) is joined to a printed wiring board (1) through solder joint sections (3). The printed wiring board (1) has through holes (11) formed therein and terminals (12) formed thereon so as to close front surface apertures which are formed by the through holes (11) in the mounting surface of the printed wiring board (1). The solder joint sections (3) are provided on the terminals (12), respectively. The solder joint sections (3) are formed by heating by light (heat rays) applied to the rear side of the printed wiring board (1) by way of the terminals (12) on the printed wiring board (1), so that heat is not transmitted to the camera module (2). Accordingly, the camera module structure (100) mounted on the printed wiring board (1) is realized without heat damage to the heat-sensitive camera module (2).

### TECHNICAL FIELD

The present invention relates to a solder mounting structure in which a heat-sensitive electronic component is mounted on the wiring board without being damaged by heat, manufacturing method and apparatus of the solder mounting structure, an electronic apparatus including the solder mounting structure, and a wiring board suitable for the solder mounting structure.

### BACKGROUND ART

As a method of mounting an electronic component such as an integrated circuit (IC), a resistor, and a capacitor on a printed board by soldering, soldering using a reflow device or a solder flow tank has been performed. Especially, the reflow device has been frequently used in recent years.

The reflow device places a printed board with an electronic component mounted thereon into a reflow furnace to perform soldering. Thus, the reflow device is useful in that it is flexibly adaptable to soldering of a printed board of complex shape.

The major advantage obtained by using these soldering methods is self-alignment. Self-alignment is the technique of using surface tension and viscosity at the solder melting to align a printed board and an electronic component. Self-alignment is frequently used in the surface-mount soldering technique.

As another soldering method, spot soldering has been proposed in which only a part to be soldered is locally heated for soldering. This soldering method uses a halogen lamp or hot wind for heating.

For example, Patent document 1 discloses soldering using a halogen lamp. Soldering disclosed in Patent document 1 is the technique of heating a target by converging light of a halogen lamp and applying heat rays in a spot to an IC package mounted on a printed board.

Patent document 2 discloses the arrangement of a welding machine adopting a thermocompression bonding method using pulse heat. In this arrangement, soldering is performed by a thermocompression bonding method in which a pulsed current is passed through a heater chip to instantly apply heat to a part to be soldered. In this arrangement, soldering is normally performed with heat applied to a part to be soldered by conducting the rear surface of a printed board or a base material of a printed board (for example, polyimide resin in the case of using a flexible printed wiring board).

[Patent document 1]

Japanese Unexamined Patent Publication No. 85708/2005 (Tokukai 2005-85708; published on Mar. 31, 2005)

[Patent document 2]

Japanese Unexamined Patent Publication No. 162538/1997 (Tokukaihei 9-162538; published on Jun. 20, 1997)

### DISCLOSURE OF INVENTION

However, the conventional methods are not suitable for mounting of a heat-sensitive component (e.g. camera module).

For example, a camera module is constituted by optical components such as a lens and an infrared cut filter and a driving section including a zoom and automatic focus. For the driving section, a magnet is used.

Soldering using a reflow device is the technique of soldering with a melted solder in a reflow furnace in which a temperature is increased to around a solder melting temperature (around 230° C.). A temperature in the reflow furnace exceeds 200° C.

However, a heat-resistance temperature (temperature that holds optical functions and properties) of the optical components of the camera module is 80° C., which is lower than the temperature in the reflow furnace. Further, a magnet used for the driving section of the camera module is likely to be demagnetized by exposure to a high temperature.

Generally, a temperature at which magnetic force is lost is called Curie temperature. Curie temperatures of a ferrite magnet and an alnico magnet are normally about 450° C. and 850° C., respectively. However, their magnetic forces tend to become weak, although magnetic forces are not lost, at temperatures lower than their Curie temperatures at which their magnetic forces are lost. Especially, assuming that magnet force of a ferrite magnet, which is demagnetized to a large degree by heat, is 100% at 20° C., magnet force decreases to about 90% at 50° C., about 80% at 100° C., and about 50% at 200° C. However, it is said that the ferrite magnet nearly recovers its original magnetic force even if a temperature is increased to around 200° C.

Thus, the reflow device places not only the printed board but also the camera module mounted on the printed board into the reflow furnace. Furthermore, the camera module includes heat-sensitive optical components and magnet. On this account, by using the reflow device, the camera module cannot be soldered to a relay connection board used when installed in a mobile phone or a digital still camera.

Note that the reflow device is assumed to be applied to soldering of various sized boards including a small memory card (e.g. 2.7 mm×3.7 mm) and a mother board (305 mm×245 mm) of a personal computer. Further, the reflow device needs to evenly heat the whole printed board and the electronic component mounted thereon. The reflow device needs to heat a large area, which requires a wide range of temperature control (temperature adjustment, constancy of temperature, and maintaining of uniform temperature distribution). As a result, the reflow device must be increased. In addition, the use of Pb-free solder, which has been recently increased in consideration of environmental concerns, makes it difficult for the reflow device to perform temperature control due to difference between a solder melting temperature (230° C.) and heat-resistance temperature of IC components (260° C.).

Incidentally, an object of the technique disclosed in Patent document 1 is to perform resoldering, not soldering of an IC package (QFP, PGA, etc.). That is, the technique disclosed in Patent document 1 is not a technique of soldering. By soldering to which the technique disclosed in Patent document 1 is applied, a heat-sensitive electronic component like a camera module cannot be mounted on a printed board. That is, as in the case with the reflow device, Patent document 1 applies light of a halogen lamp to the surface of the printed board where an IC package (electronic component) is mounted, with the electronic component mounted on the printed board. In other words, the whole electronic component is heated even in Patent document 1. As a result, not only optical components of the camera module are damaged by heating, but also a sensor device (IC) is damaged by intense light into which light of a halogen lamp is converged.

Therefore, the technique disclosed in Patent document 1 cannot be applied to soldering of a heat-sensitive electronic component.

On the other hand, the arrangement disclosed in Patent document 2 is superior at the present time especially in that it does not give heat stress to the optical components of the camera module. On this account, current soldering of the camera module to a printed board is performed, applying the arrangement disclosed in Patent document 2.

However, in the arrangement disclosed in Patent document 2, solder is melted by heating the backside of the printed board. In this method, in order to melt the solder, it is required to heat the backside of the board to a much higher temperature than a melting temperature of the solder. As a result, bubbles are generated on the solder joint section of the printed board due to thermal stress. This causes deformation of the printed board and insufficient soldering, thus resulting in poor soldering.

Besides, the camera module is soldered to the printed board while they are pressed mechanically. This causes misalignment between the printed board and the camera module.

The present invention has been attained in view of the above problems, and an object of the present invention is to provide a solder mounting structure in which a heat-sensitive electronic component is mounted on the wiring board without being damaged by heat, a manufacturing method and a manufacturing apparatus of the solder mounting structure, and a wiring board suitable for the solder mounting structure.

In order to achieve the above object, a solder mounting structure of the present invention is a solder mounting structure in which an electronic component is mounted on a wiring board through solder joint sections, wherein the wiring board has (i) through holes formed therein that penetrate the wiring board, extending from a mounting surface of the wiring board where the electronic component is mounted to a rear surface thereof, and (ii) terminals formed thereon so as to close front surface apertures which are formed by the through holes in the mounting surface, and the solder joint sections are provided on the respective terminals.

According to the above arrangement, the through holes are formed in the wiring board. The apertures (front surface apertures) formed by the through holes on the mounting surface side of the wiring board are closed by the terminals, respectively. On the terminals, the solder joint sections are formed. With this arrangement, it is possible to solder the electronic component by heating the solder joint sections by way of the terminals from the rear surface of the wiring board. That is, it is unnecessary to directly heat the electronic component. Therefore, it is possible to provide a solder mounting structure in which the electronic component is mounted on the wiring board without heat damage to the heat-sensitive electronic component.

In order to achieve the above object, a method for manufacturing a solder mounting structure according to the present invention is a method for manufacturing any one of the solder mounting structures, including: a heating step of heating the solder joint sections by way of the terminals by light irradiation to the rear surface of the wiring board.

According to the above method, the solder joint sections are heated by light irradiation to the rear surface of the wiring board. That is, since the solder joint sections are heated by way of the terminals from the rear surface of the wiring board, the electronic component is not heated directly. With this arrangement, it is possible to mount the electronic component on the wiring board without heat damage to the electronic component.

Therefore, it is possible to preferably manufacture a solder mounting structure in which the electronic component is mounted on the wiring board without heat damage to the heat-sensitive electronic component.

In order to achieve the above object, a manufacturing apparatus of a solder mounting structure of the present invention is a manufacturing apparatus of a solder mounting structure of the present invention, including: a stage, on which the wiring board is placed, having stage through holes formed therein that get through to the through holes of the wiring board; and a light irradiation section that heats the solder joint sections by light irradiation to the rear surface of the wiring board.

According to the above arrangement, the stage has the stage through holes formed therein that get through to the through holes of the wiring board. The light applied to the rear surface of the wiring board by the light irradiation section enters the stage through holes, goes through the through holes of the wiring board, and reaches the terminals. This makes it possible to heat the solder joint sections by way of the terminals. That is, since the solder joint sections are heated from the rear surface of the wiring board by way of the terminals, the electronic component is not heated directly. With this arrangement, it is possible to mount the electronic component on the wiring board without heat damage to the electronic component. Therefore, it is possible to preferably manufacture a solder mounting structure in which the electronic component is mounted on the wiring board, without heat damage to the heat-sensitive electronic component.

In order to achieve the above object, a wiring board of the present invention is a wiring board on which an electronic component is mounted by way of solder joint sections, the wiring board having (i) through holes formed therein that penetrate the wiring board, extending from a mounting surface of the wiring board where the electronic component is mounted to a rear surface thereof, and (ii) terminals formed thereon so as to close front surface apertures which are formed by the through holes in the mounting surface.

According to the above arrangement, the through holes are formed in the wiring board. The apertures (front surface apertures) formed by the through holes on the mounting surface side of the wiring board are closed by the terminals, respectively. On the terminals, the solder joint sections are formed. With this arrangement, it is possible to provide a wiring board on which the electronic component can be soldered by heating the solder joint sections by way of the terminals from the rear surface of the wiring board. Therefore, it is possible to provide a wiring board suitable for a solder mounting structure in which the electronic component is mounted on the wiring board without heat damage to the heat-sensitive electronic component.

As described above, a solder mounting structure of the present invention is arranged such that the terminals are formed so as to close the front surface apertures formed by the through holes in the mounting surface of the wiring board, and the solder joint sections are provided on the respective terminals.

A method for manufacturing a solder mounting structure according to the present invention includes: a heating step of heating the solder joint sections by way of the terminals by light irradiation to the rear surface of the wiring board.

A manufacturing apparatus of a solder mounting structure according to the present invention includes: a stage, on which the wiring board is placed, having stage through holes formed therein that get through to the through holes of the wiring board; and a light irradiation section that heats the solder joint sections by light irradiation to the rear surface of the wiring board.

According to the above arrangements, since the solder joint sections are heated by way of the terminals from the rear surface of the wiring board, the electronic component is not heated directly. With this arrangement, it is possible to mount the electronic component on the wiring board without heat damage to the electronic component. Therefore, it is possible to provide a solder mounting structure in which the electronic component is mounted on the wiring board without heat damage to the heat-sensitive electronic component.

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1 is a cross-sectional view of a camera module according to the present invention.

FIG. 2 is a plan view of a printed wiring board of the camera module illustrated in FIG. 1.

FIG. 3 is a cross-sectional view of the printed wiring board viewed along line A-A in FIG. 2 and a partially exploded view thereof.

FIG. 4 is a cross-sectional view of the printed wiring board of FIG. 3 having a solder joint section formed thereon and a partially exploded view thereof.

FIG. 5(a) is a view illustrating a method of forming solder joint sections.

FIG. 5(b) is a view illustrating a method of forming solder joint sections.

FIG. 6 is a cross-sectional view of a step for manufacturing the camera module illustrated in FIG. 1.

FIG. 7 is a cross-sectional view of a step for manufacturing the camera module illustrated in FIG. 1.

FIG. 8 is a cross-sectional view of a step for manufacturing the camera module illustrated in FIG. 1.

FIG. 9 is a cross-sectional view of a step for manufacturing the camera module illustrated in FIG. 1.

FIG. 10 is a cross-sectional view of a step for manufacturing the camera module illustrated in FIG. 1.

FIG. 11 is a cross-sectional view of a step for manufacturing the camera module illustrated in FIG. 1.

FIG. 12 is a view of a manufacturing apparatus of the camera module illustrated in FIG. 1.

### BEST MODE FOR CARRYING OUT THE INVENTION

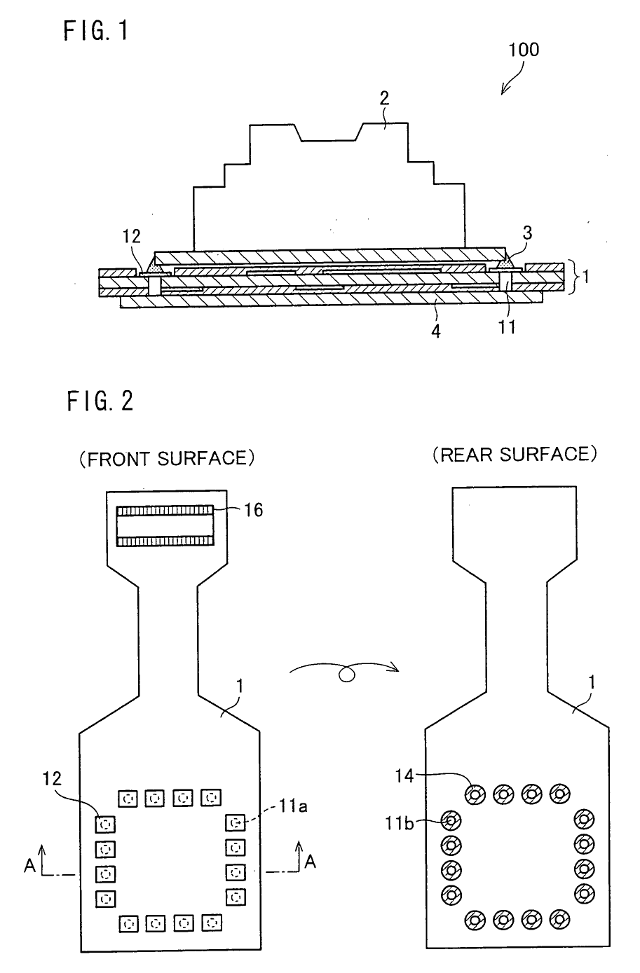

The following will describe an embodiment of the present invention with reference to FIGS. 1 through 12. It should be noted that the present invention is not limited by the following description.

The present embodiment describes a camera module structure (solder mounting structure) provided in an electronic device, such as a mobile phone and a digital still camera. FIG. 1 is a partial cross-sectional view of a camera module structure 100 of the present embodiment.

The camera module structure (solder mounting structure) 100 of the present embodiment is arranged such that a printed wiring board (wiring board) 1 and a camera module (electronic component; optical component) 2 are joined together by a solder joint section 3. In addition, the camera module structure 100 includes a reinforcing board 4 on the surface of the printed wiring board 1 which surface is opposite to the surface where the camera module 2 is mounted. The following description assumes that the surface of the printed wiring board 1 where the camera module 2 is mounted is a front surface and the other surface is a rear surface.

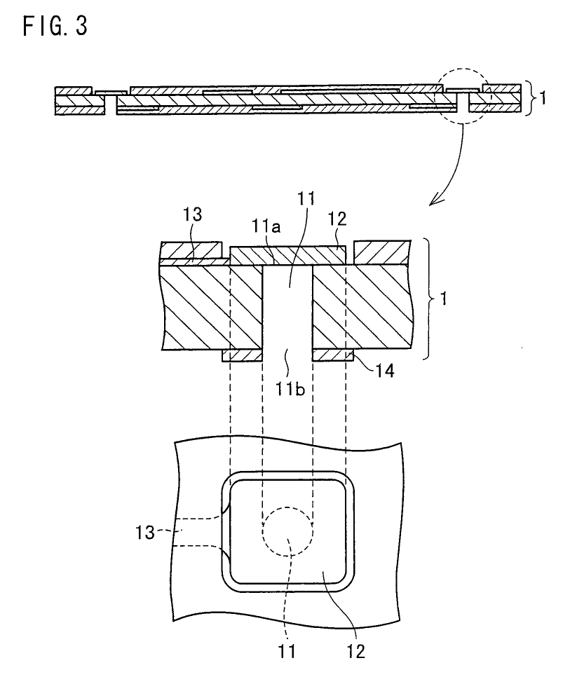

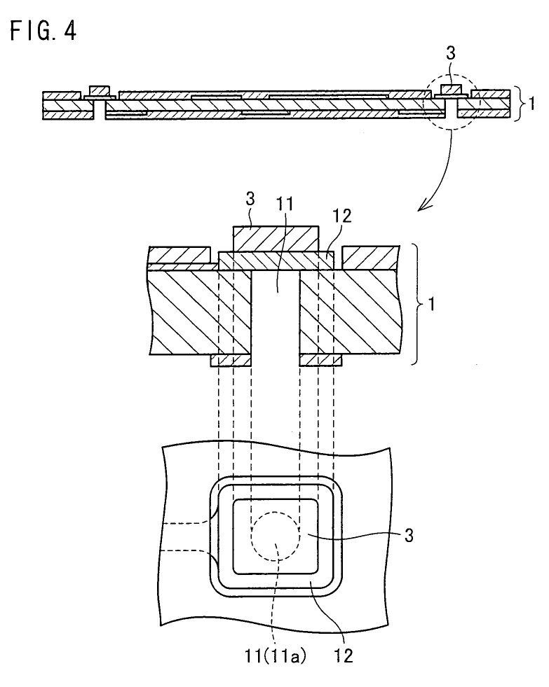

FIG. 2 is a plan view of the front and rear surfaces of the printed wiring board 1. FIG. 3 is a cross-sectional view of the printed wiring board 1 viewed along line A-A in FIG. 2 and a partially exploded view thereof. FIG. 4 is a cross-sectional view of the printed wiring board 1 of FIG. 3 having the solder joint section 3 formed thereon and a partially exploded view thereof.

The printed wiring board 1 is a sheet-type board as illustrated in FIGS. 2 and 3. The printed wiring board 1 is, for example, a flexible wiring board (also termed Flexible Print Circuit (FPC)). Type and material of the printed wiring board 1 are not particularly limited.

The printed wiring board 1 has a through hole 11 that penetrates the printed wiring board 1, extending from its front surface (mounting surface) to its rear surface. On the front surface (mounting surface) of the printed wiring board 1, a plurality of terminals 12, a wiring pattern 13 (not shown in FIG. 2), and a connector 16 are formed.

The terminals 12 are formed around the area where the camera module 2 is mounted. The terminal 12 is formed so as to close an aperture (front surface aperture) 11a formed in the mounting surface of the printed wiring board 1 by the through hole 11. The terminal 12 is made from metal such as a gold-plated copper foil. As illustrated in FIG. 4, the solder joint section 3 for soldering the camera module 2 is formed on the terminal 12. Since the terminal 12 is in contact with the wiring pattern 13, there is electrical continuity between the printed wiring board 1 and the camera module 2 through the solder joint section 3.

The connector 16 (FIG. 2) is the one by which the camera module structure 100 is electrically connected to other component. The connector 16 is formed in an area other than the area where the camera module 2 is mounted.

For example, the connector 16 transmits the image data taken by the camera module 2 to other member. As such, the printed wiring board 1 also functions as a relay board.

As illustrated in FIG. 3, reflection layers 14 are formed on the rear surface of the printed wiring board 1. Each of the reflection layers 14 is formed around an aperture (rear surface aperture) 11b formed in the rear surface of the printed wiring board 1 by the through hole 11. The reflection layer 14 reflects light applied to the rear surface of the printed wiring board 1 (specifically, heat rays emitted from a halogen lamp, as will be described later). For example, the reflection layer 14 may be an infrared-ray reflection layer that reflects infrared rays (near-infrared rays) emitted from a halogen lamp. Near-infrared rays are highly selective and reflected by a white object. Therefore, in order to make the reflection layer 14 reflect near-infrared rays, the reflection layer 14 should be, for example, a white layer formed by silkscreen printing or the like method.

The camera module 2 is a lens member (optical component) which is to be installed in a mobile phone, a digital still camera, or the like. On an undersurface of the camera module 2, a plurality of terminals (not shown) are formed corresponding to the terminals 12 of the printed wiring board 1. The terminals 12 formed on the printed wiring board 1 and the terminals formed on the camera module 2 are positioned to face each other, and the printed wiring board 1 and the camera module 2 are joined together by the solder joint section 3, which is provided between the printed wiring board 1 and the camera module 2. With this arrangement, electrical signals of the camera module 2 are transmitted to the printed wiring board 1 via the solder joint section 3. That is, electrical signals of the printed wiring board 1 and the camera module 2 are inputted/outputted via the solder joint section 3.

Thus, the camera module structure 100 is arranged such that the camera module 2 is joined onto the front surface of the printed wiring board 1 via the solder joint section 3.

As illustrated in FIG. 1, a reinforcing board 4 is formed on the rear surface of the printed wiring board 1. The reinforcing board 4 is provided so as to close the rear surface aperture 11b. The reinforcing board 4 is preferably made from polyimide resin, for example, and has the function of mitigating shock given to the camera module 2. In the present embodiment, the reinforcing board 4 is preferably made from a transparent (light-transmitting) material that allows light for heating the solder joint section 3 to pass through, since the solder joint section 3 is heated by light radiation. This will be described later.

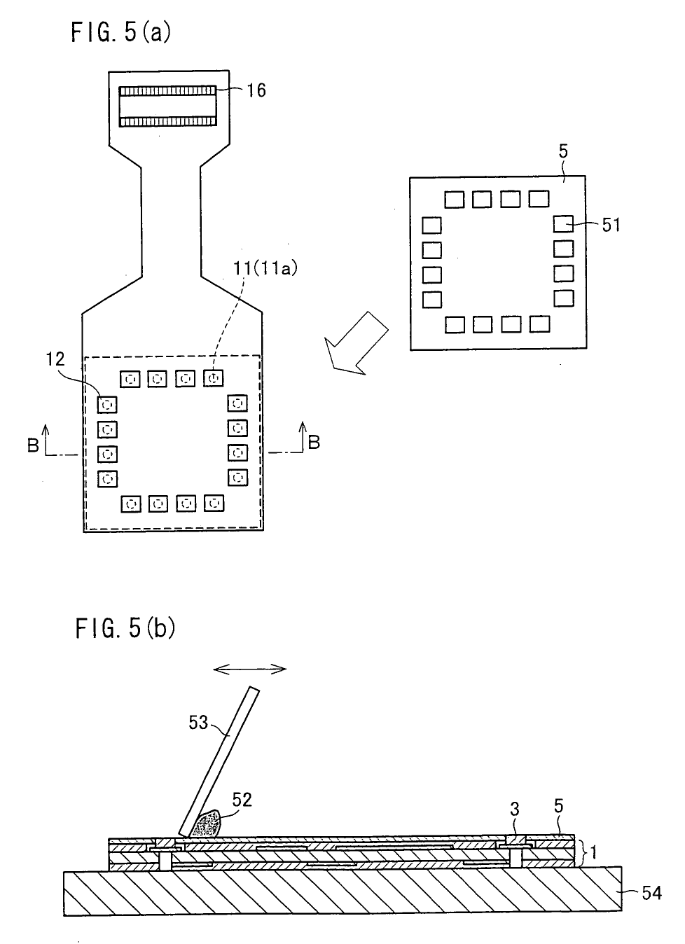

Next, an example of a method for manufacturing the camera module structure 100 is described. FIGS. 5(a) through 11 are views illustrating the manufacturing process in the manufacturing method.

Conventionally, a part to be soldered was heated mainly from the mounting surface side in order that an electronic component is surface-mounted on a wiring board by solder-joining. However, this raises the problem that a heat-sensitive electronic component, such as camera module, is damaged by heating during the mounting.

In view of this, in the method for manufacturing the camera module structure 100 according to the present embodiment, the solder joint section 3 is heated from the rear surface of the printed wiring board 1 by way of the terminal 12. This allows only the solder joint section 3 to be heated selectively, thus preventing the camera module 2 from being damaged by heat.

The following will describe the manufacturing method of the camera module structure 100 in detail.

First of all, the solder joint sections (solder pads) 3 are formed on the printed wiring board 1 having the through holes 11 and terminals 12. FIGS. 5(a) and 5(b) are views illustrating a method of forming the solder joint sections 3. FIG. 5(b) is a cross-sectional view, viewed along line B-B in FIG. 5(a). The formation of the solder joint sections 3 is performed by solder printing using a solder mask 5, as illustrated in FIG. 5(a). The solder mask 5 has openings 51 corresponding to the terminals 12 of the printed wiring board 1. An area of the opening 51 is slightly smaller than that of the terminal 12.

As indicated by a dashed line in FIG. 5(a), the solder mask 5 is placed on the printed wiring board 1 in the area where the solder joint sections 3 are formed, so that the openings 51 are positioned on the terminals 12 of the printed wiring board 1. At this time, the printed wiring board 1 is placed on a stage 54, as illustrated in FIG. 5(b). Next, a solder paste (cream solder) 52 supplied on the solder mask 5 is applied thereon by a squeegee (spatula) 53 so as to be spread across the solder mask 5. This ensures the solder paste 52 to be supplied in the openings 51. When the solder mask 5 is removed after a lapse of a given time period, the solder joint sections 3 are formed on the terminals 12.

Either the formation of the through holes 11 or the formation of the terminals 12 may go first. However, in a case where the formation of the terminals 12 is followed by the formation of the through holes 11, care should be taken not to penetrate the terminals 12.

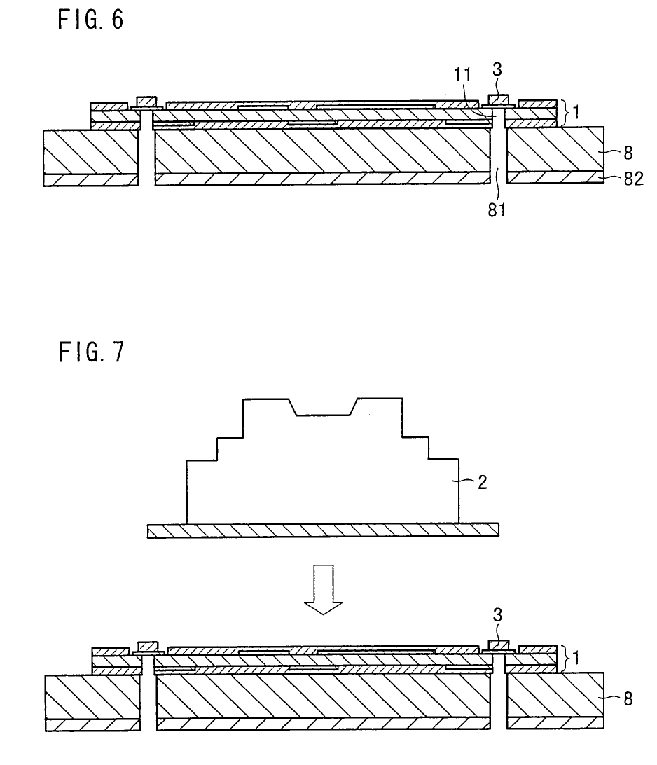

Next, the printed wiring board 1 on which the solder joint sections 3 are thus formed is placed on the stage 8 as illustrated in FIG. 6. In the stage 8, stage through holes 81 are formed. The stage through holes 81 are formed so as to get through to the through holes 11 of the printed wiring board 1. The stage through hole 81 includes the rear surface aperture 11b of the printed wiring board 1. In other words, the diameter of the stage through hole 81 is greater than that of the rear surface aperture 11b. That is, the width of the stage through hole 81 in the horizontal direction is greater than that of the through hole 11 in the horizontal direction.

On the rear surface of the stage 8 (surface opposite to the surface where the printed wiring board 1 is placed), a reflection layer (first reflecting section) 82, which is similar to the reflection layer 14 of the printed wiring board 1, is formed.

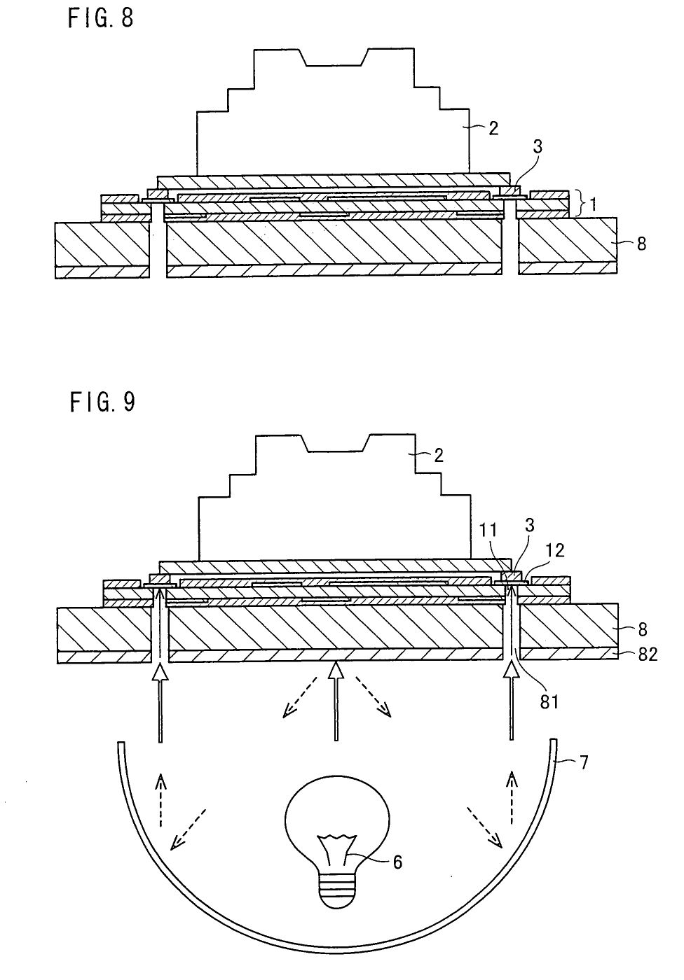

Next, the camera module 2 is placed on the printed wiring board 1 positioned on the stage 8, as illustrated in FIGS. 7 and 8. The camera module 2 is placed in such a manner that the terminals (not shown) of the camera module 2 substantially correspond to the solder joint sections 3. It is unnecessary to make the terminals of the camera module 2 precisely coincide with the solder joint section 3 since the present embodiment employs self-alignment of solder, as will be described later.

Then, the solder joint sections 3 are heated from the backside (rear side) of the stage 8, as illustrated in FIG. 9. That is, the solder joint sections 3 are heated in a selective manner by way of the terminals 12 from the backside of the printed wiring board 1. More specifically, a halogen lamp (light irradiation section) 6 is provided on the backside of the stage 8 in the present embodiment. That is, the solder joint sections 3 are heated by irradiation with heat rays of the halogen lamp 6 in the present embodiment. The halogen lamp 6 emits heat rays (infrared rays or near-infrared rays). Thus, the halogen lamp 6 is an optical heating device which heats the solder joint sections 3 by light irradiation.

Around the halogen lamp 6 except for the area on the side of the stage 8, a concave mirror (second reflecting section) 7 is provided. The concave mirror 7 reflects light reflected by the reflection layer 82, toward the stage 8.

With this arrangement, light emitted from the halogen lamp 6, as indicated by an arrow in FIG. 9, goes through the through holes 81 and the through holes 11 of the printed wiring board 1 and then reaches the terminals 12. Since the halogen lamp 6 emits intense heat rays, the solder joint sections 3 are heated by heat that has reached the terminals 12. The terminal 12, which is made from metal, have an excellent thermal conductivity. Therefore, the terminal 12 has a high efficiency of thermal conductivity with respect to the solder joint section 3.

When the solder joint sections 3 are heated by way of the terminals 12, the printed wiring board 1 and the camera module 2 are aligned with high precision due to the self-alignment effect of melted solder. A way to obtain the self-alignment effect is to make light emitted from the halogen lamp 6 enter all the stage through holes 81 formed in the stage 8, so that all the terminals 12 formed on the printed wiring board 1 are heated at once. That is, all the terminals 12 on which the solder joint sections 3 are provided are heated at once.

Of the light emitted from the halogen lamp 6, light that has not reached the stage through holes 81 is reflected by the reflection layer 82 formed on the rear surface of the stage 8, as indicated by a dashed arrow in FIG. 9. Further, the light reflected by the reflection layer 82 is reflected by the concave mirror 7 when reaching the concave mirror 7. The light reflected by the concave mirror 7 is reflected toward the stage 8 again, so that the reflected light is used to heat the solder joint sections 3. In this manner, the concave mirror 7 and the reflection layer 82 of the stage 8 allow light emitted from the halogen lamp 6 to be used efficiently to heat the solder joint sections 3.

In this manner, soldering of the printed wiring board 1 and the camera module 2 is completed.

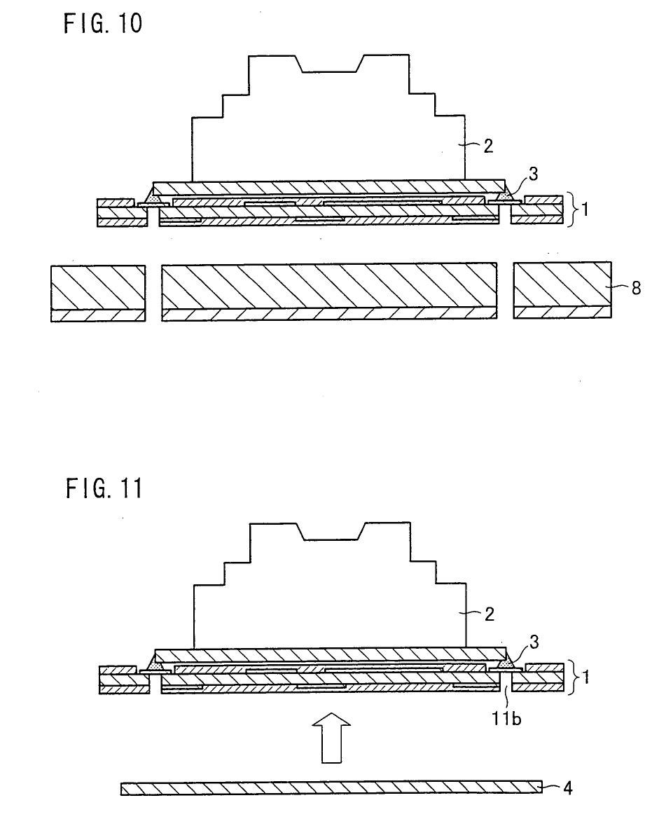

Next, as illustrated in FIG. 10, the joined printed wiring board 1 and camera module 2 are lifted from the stage 8. Then, as illustrated in FIG. 11, the reinforcing board 4 is attached to the backside of the printed wiring board 1. This completes the manufacture of the camera module structure 100 illustrated in FIG. 1.

Note that the reinforcing board 4 is formed so as to close the apertures (rear surface apertures 11b) in the backside of the printed wiring board 1. The reinforcing board 4 prevents, for example, (i) the separation of the camera module 2 and (ii) breaks of the wiring pattern 13 formed on the printed wiring board 1, both of which are caused by load applied at the installation of the printed wiring board 1 into a mobile phone after the camera module 2 is soldered to the printed wiring board 1. Before the reinforcing board 4 is formed, the through holes 11 may be subjected to corrosion-proofing treatment or the like.

The stage 8 and the halogen lamp 6, preferably the stage 8, the halogen lamp 6, and the concave mirror 7, which are used in the manufacture of the camera module structure 100 of the present embodiment, can be also referred to as a manufacturing apparatus of the camera module structure 100.

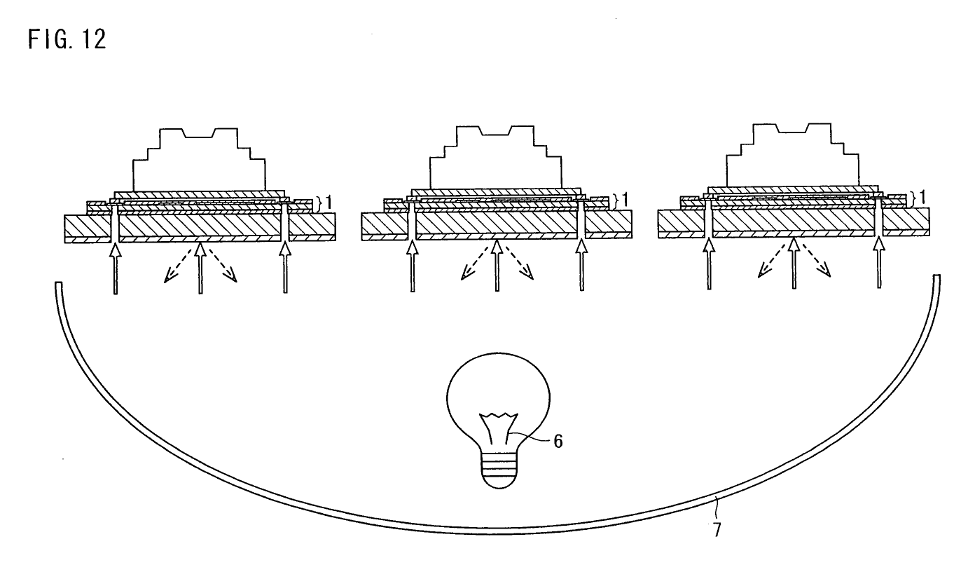

The manufacturing apparatus of the camera module structure 100 of the present embodiment is arranged such that one halogen lamp 6 heats one printed wiring board 1, as illustrated in FIG. 9. However, the manufacturing apparatus is preferably arranged such that one halogen lamp 6 heats a plurality of printed wiring boards 1 at once, as illustrated in FIG. 12. This makes it possible to manufacture a plurality of camera module structures 100 at once, thus increasing productivity.

As described above, the camera module structure 100 of the present embodiment is arranged such that the terminals 12 are formed so as to close the front surface apertures 11a which are formed in the mounting surface of the printed wiring board. 1 by the through holes 11, and the solder joint sections 3 are provided on the respective terminals 12. This makes it possible to heat the solder joint sections 3 by way of the terminals 12 by light irradiation to the rear surface of the printed wiring board 1. Thus, it is possible to solder the camera module 2 by heating the solder joint sections 3 by way of the terminals 12 from the rear surface of the printed wiring board 1. That is, it is possible to mount the camera module 2 on the printed wiring board 1 without directly heating the camera module 2. Therefore, it is possible to mount the camera module 2 on the printed wiring board 1 without heat damage to the camera module 2.

In the present embodiment, the reflection layer 14 is formed so as not to close the rear surface aperture 11b. Each of the reflection layers 14 is preferably formed around the rear surface aperture 11b. As described previously, the stage through hole 81 includes the rear surface aperture 11b. With this arrangement, light going through the stage through hole 81 enters the perimeter of the rear surface aperture 11b. That is, the rear surface of the printed wiring board 1 is irradiated with light. Thus, with the arrangement where the reflection layer 14 is formed around the rear surface aperture 11b, it is possible to reflect the light entering the rear surface of the printed wiring board 1. This makes it possible to prevent thermal conduction from the rear surface of the printed wiring board 1 to the camera module 2. This allows only the terminal 12 to be heated, thus heating the solder joint sections 3 in a selective manner.

In the present embodiment, the reinforcing board 4 is formed so as to close the rear surface apertures 11b. With this arrangement, it is possible to prevent the solder joint sections 3 from being separated when the camera module structure 100 is pressed. Further, it is possible to prevent breaks of the wiring pattern 13 formed on the printed wiring board 1. The reinforcing board 4 is preferably made from polyimide resin capable of resisting a solder melting temperature. When the reinforcing board 4 made from resin containing glass fiber or the like fiber is cut in the manufacture process, fine splits occur on the cut reinforcing board, which splits may scratch the printed wiring board 1. The use of the reinforcing board 4 made from polyimide resin can prevent the printed wiring board 1 from being damaged.

In the present embodiment, heating by means of heat rays like infrared rays or near-infrared rays is performed using the halogen lamp 6. This makes it possible to ensure the heat rays to reach the terminals 12, thus heating the solder joint sections 3 in a selective manner. The use of the halogen lamp 6 allows for easy heating temperature control. Thus, by controlling the heating temperature, it is possible to make the self-alignment effect obtained by melted solder greater than that of the conventional reflow method.

In the conventional reflow method, convective heat (i.e. hot wind) is used for heating. In this case, the amount of hot wind flow must be increased to enhance heat efficiency. However, the increase of the amount of hot wind flow, i.e. a strong hot wind causes misalignment of the components to be mounted.

On the contrary, in the present embodiment, the use of the halogen lamp 6 enables the rear surface of the printed wiring board 1 to be exposed to light as a medium, thereby heating the rear surface of the printed wiring board 1. This causes no adverse effects of the hot wave and thus prevents the misalignment of the components to be mounted.

The halogen lamp 6 uses light (electromagnetic waves: near-infrared rays (infrared rays of not longer than 2.5 μm) emitted from a heating element (filament) heated at 2000° C. to 2800° C. in an electric bulb in which halogen gas (or its element) is filled at a high pressure. A peak wavelength of the light is approximately 1 μm (0.001 mm), and the distribution of the wavelength of the light is in the range of approximately 0.53 μm. That is, the halogen lamp 6, which emits visible light as well, is in a broad sense an infrared heater employing temperature radiation. Temperature radiation means electromagnetic waves (light in a broad sense) emitted from a substance when the substance is heated to high temperature. An optical heating method other than the temperature radiation includes laser heating. In the present embodiment, the halogen lamp 6 is used to perform heating by light irradiation. However, a tungsten lamp, a laser (semiconductor laser), or others can be used.

Note that heating with the use of the near-infrared heater, such as the halogen lamp 6, has the characteristics that when light is emitted to printed paper, for example, a printed character area is intensely heated while a non-printed area is not heated. On the contrary, a far-infrared heater heats the whole area of the paper. That is, near-infrared rays have the characteristics that wide absorption variations occur depending upon a surface state (color etc.) of an object to be heated, i.e. near-infrared rays have selectivity in the degree of heating. More specifically, an absorption rate of near-infrared rays varies depending upon an object to be heated. The absorption rate is approximately 10% in a blank (white) area of printed paper, 30% in a glossy surface of stainless steel, and 80% in an oxidized surface of stainless steel. In addition, the halogen lamp 6 converts electrical power into light at a high efficiency of approximately 85%. Therefore, it is particularly preferable to use the halogen lamp 6.

In the present embodiment, the stage 8, on which the printed wiring board 1 is to be placed, has the stage through holes 81 that get through to the through holes 11 of the printed wiring board 1. With this arrangement, light emitted from the halogen lamp 6 to the rear surface of the printed wiring board 1 reaches the terminals 12, passing through the stage through holes 81 and the through holes 11 of the printed wiring board 1. As a result, the solder joint sections 3 can be heated by way of the terminals 12. This avoids the camera module 2 from being directly heated.

In the present embodiment, the rear surface of the stage 8 has the reflection layer 82 that reflects light (heat rays) emitted from the halogen lamp 6. This makes it possible to irradiate the stage through holes 81 with the light from the halogen lamp 6, while allowing the reflection layer 82 to reflect light entering the area other than the stage through holes 81. Therefore, it is possible to ensure light irradiation to the area to be irradiated with light, and reflect light entering the reflection layer 82 (first reflecting section) formed corresponding to the other area where light irradiation is not needed. Such an effect becomes the greatest if the reflection layer 82 is formed in an area other than the apertures of the stage through holes 81.

In addition, in the present embodiment, the concave mirror 7 is provided to make the light reflected by the reflection layer 82 reflect toward the stage 8. This makes it possible to reuse light reflected by the reflection layer 82 to heat the solder joint sections 3.

In the present embodiment, a heating temperature and a heating time of the solder joint section 3 may be set in consideration of a melting temperature of solder to be used, a heat-resistance temperature (heat resistance) of the electronic component to be mounted on the printed wiring board 1, and other factor. That is, the heating temperature and the heating time, which are not particularly limited, may be set in such a range that the printed wiring board 1 and the camera module 2 are not damaged due to heat.

Heating of the solder joint section 3 (heating of the terminals 12) can be performed according to a thermal profile for melting the solder. For example, the solder is temporally kept at a preheat temperature (Tp) lower than the solder melting temperature of the solder joint section 3, thereby evenly distributing the temperature over the terminals 12 (preheat). Thereafter, the solder is heated to a temperature equal to or higher than the solder melting temperature (T1) of the solder joint section 3, and is rapidly cooled in order to prevent the graining of the solder (main heating).

The solder melting temperature of the solder joint sections 3 is not particularly limited. However, it is preferably, for example, in the range from 140° C. to 219° C., more preferably in the range from 183° C. to 190° C.

In addition, the type of solder used for the solder joint section 3 is not particularly limited; however, it is environmentally preferable to use the so-called Pb-free solder. The Pb-free solder may be, but not limited to, Sn—Ag type solder, Sn—Zn type solder, Sn—Bi type solder, Sn—In type solder, or Sn—Ag—Cu type solders. In addition, the compositional proportion of the solder constituents is also not particularly limited.

In addition, the solder of the solder joint section 3 may have flux therein. In other words, the solder may be solder paste (cream solder) containing a flux agent or the like. This provides the solder with greater wettability and flowability. This brings a greater self-alignment effect.

The type of flux is not particularly limited, and may be set according to the constituents of the electrodes formed on the electronic component and the board respectively. For example, the flux may be corrosive flux (ZnCl₂-NH₄Cl type mixed salt etc.), slow flux (organic acid and its derivatives etc.), non-corrosive flux (a mixture of rosin and isopropyl alcohol), aqueous flux (rosin-type flux etc.), low-residue flux (rosin-type or resin-type flux with solid constituent of 5% or less and the activating agent as organic acid) or the like.

In the present embodiment, the camera module 2 has been taken as an example of an electronic component mounted on the printed wiring board 1. However, the electronic component is not limited to the camera module 2. The electronic component may be, for example, a semiconductor chip, IC chip, or the like. Particularly, it is preferably an optical element (optical component) sensitive to heat. Examples of such an optical element include a lens module into which a lens, an infrared cut filter, and a sensor device are integrated.

As described above, a solder mounting structure of the present invention is a solder mounting structure in which an electronic component is mounted on a wiring board through solder joint sections, the wiring board having (i) through holes formed therein that penetrate the wiring board, extending from a mounting surface of the wiring board where the electronic component is mounted to a rear surface thereof and (ii) terminals formed thereon so as to close front surface apertures which are formed by the through holes in the mounting surface, the solder joint sections being provided on the respective terminals.

According to the above arrangement, the through holes are formed in the wiring board. The apertures (front surface apertures) formed by the through holes on the mounting surface side of the wiring board are closed by the terminals, respectively. On the terminals, the solder joint sections are formed. With this arrangement, it is possible to solder the electronic component by heating the solder joint sections by means of the terminals from the rear surface of the wiring board. That is, it is unnecessary to directly heat the electronic component. Therefore, it is possible to provide a solder mounting structure in which the electronic component is mounted on the wiring board without heat damage to the heat-sensitive electronic component.

A solder mounting structure of the present invention is preferably such that on the rear surface of the wiring board, reflection layers are provided to reflect light applied to the rear surface of the wiring board, the reflection layers being formed so as not to close rear surface apertures, which are formed by the through holes in the rear surface of the wiring board.

According to the above arrangement, the reflection layers are formed so as not to close the apertures (rear surface apertures) formed by the through holes in the rear surface of the wiring board. With this arrangement, when the solder joint sections are heated by light irradiation to the rear surface of the wiring board, the area where the reflection layers are formed is not heated because light applied to the area where the reflection layers are formed is reflected. On the other hand, light applied to the rear surface apertures of the wiring board, which are not closed by the reflection layers, go through the through holes and reaches the terminals. Thus, the solder joint sections are heated by way of the terminals. Therefore, it is possible to ensure heating of the area (i.e. terminals) to be heated, and prevent the area not to be heated from being heated by forming the reflection layers on the area not to be heated. Further, it is possible to reuse light reflected by the reflection layers to heat the solder joint sections. It is preferable that the each of the reflection layers is formed around the rear surface aperture of the wiring board.

A solder mounting structure of the present invention is preferably arranged such that a reinforcing board is formed so as to close the rear surface apertures.

According to the above arrangement, the reinforcing board is formed on the rear surface of the wiring board. With this arrangement, it is possible to prevent the terminals and the solder joint sections on the printed board from being separated when the solder mounting structure is pressed. Further, it is possible to prevent breaks of the wiring pattern formed on the wiring board.

A method for manufacturing a solder mounting structure according to the present invention is a method for manufacturing any one of the solder mounting structures, including: a heating step of heating the solder joint sections by way of the terminals by light irradiation to the rear surface of the wiring board.

According to the above method, the solder joint sections are heated by light irradiation to the rear surface of the wiring board. That is, since the solder joint sections are heated by way of the terminals from the rear surface of the wiring board, the electronic component is not heated directly. With this arrangement, it is possible to mount the electronic component on the wiring board without heat damage to the electronic component. Therefore, it is possible to preferably manufacture a solder mounting structure in which the electronic component is mounted on the wiring board without heat damage to the heat-sensitive electronic component.

In the heating step, all the terminals on which the solder joint sections are provided may be heated at once.

According to the above method, a plurality of terminals on which the solder joint sections are formed are heated at once. This melts solder of the solder joint sections at once. With this arrangement, it is possible to align the wiring board and the electronic component with high precision by self-alignment of melted solder.

In the heating step, infrared rays or near-infrared rays may be emitted in the light irradiation.

According to the above arrangement, heating is performed by heat rays like infrared rays or near-infrared rays. This ensures the heat rays to reach the terminals, thus allowing for heating the solder joint sections.

In the heating step, the light irradiation is preferably performed by using a halogen lamp.

According to the above method, infrared rays (preferably near-infrared rays) are applied by using a halogen lamp. This makes it possible to heat the solder joint sections by way of the terminals. Further, the use of a halogen lamp makes it easy to control a heating temperature.

A manufacturing apparatus of a solder mounting structure according to the present invention is a manufacturing apparatus of any one of the solder mounting structures, including: a stage, on which the wiring board is placed, having stage through holes formed therein that get through to the through holes of the wiring board; and a light irradiation section that heats the solder joint sections by light irradiation to the rear surface of the wiring board.

According to the above arrangement, the stage has the stage through holes formed therein that get through to the through holes of the wiring board. The light applied to the rear surface of the wiring board by the light irradiation section enters the stage through holes, goes through the through holes of the wiring board, and reaches the terminals. This makes it possible to heat the solder joint sections by way of the terminals. That is, since the solder joint sections are heated from the rear surface of the wiring board by way of the terminals, the electronic component is not heated directly. With this arrangement, it is possible to mount the electronic component on the wiring board without heat damage to the electronic component. Therefore, it is possible to preferably manufacture a solder mounting structure in which the electronic component is mounted on the wiring board, without heat damage to the heat-sensitive electronic component.

A manufacturing apparatus of a solder mounting structure of the present invention is preferably arranged such that on a rear surface of the stage, a first reflecting section is provided to reflect light emitted from the light irradiation section.

According to the above arrangement, the first reflecting section is provided on the rear surface of the stage. This reflects light that enters the first reflecting section. With this arrangement, light from the light irradiation section is applied to the stage through holes, while light that enters the area other than the stage through holes is reflected by the first reflecting section.

Therefore, it is possible to ensure light irradiation to the area to be irradiated with light, and the first reflecting section, which is formed in the area not to be irradiated with light, can reflect light that enters the first reflecting section.

A manufacturing apparatus of a solder mounting structure of the present invention is preferably arranged so as to further include: a second reflecting section that reflects light reflected by the first reflecting section toward the stage.

As described previously, light reflected by the first reflecting section is light applied to the area other than the stage through holes. According to the above arrangement, the second reflecting section reflects light reflected by the first reflecting section toward the stage. With this, it is possible to reuse the light reflected by the first reflecting section for heating of the solder joint sections.

An electronic apparatus of the present invention includes any of the above solder mounting structures. With this arrangement, a solder mounting structure in which the electronic component is not damaged by heat can be provided as an electronic apparatus such as a mobile phone and a digital still camera.

A wiring board of the present invention is a wiring board on which an electronic component is mounted by way of solder joint sections, the wiring board having (i) through holes formed therein that penetrate the wiring board, extending from a mounting surface of the wiring board where the electronic component is mounted to a rear surface thereof, and (ii) terminals formed thereon so as to close front surface apertures which are formed by the through holes in the mounting surface.

According to the above arrangement, the through holes are formed in the wiring board. The apertures (front surface apertures) formed by the through holes on the mounting surface side of the wiring board are closed by the terminals, respectively. On the terminals, the solder joint sections are formed. With this arrangement, it is possible to provide a wiring board on which the electronic component can be soldered by heating the solder joint sections by way of the terminals from the rear surface of the wiring board. Therefore, it is possible to provide a wiring board suitable for a solder mounting structure in which the electronic component is mounted on the wiring board without heat damage to the heat-sensitive electronic component.

It can be also said that an object of the present invention is to provide the technique for realizing an excellent soldering a solid imaging device (camera module 2) to a board (printed wiring board 1) or others without damage to a heat-sensitive optical component.

The arrangement of the present invention for the achievement of this object can be expressed as the arrangement in which (i) a board (printed wiring board 1) in which holes (through holes 11) are formed in its rear surface at the respective areas corresponding to the terminals 12 to which an electronic component such as camera module 2 is soldered and (ii) the terminals 12 (gold-plated copper foils) each of which has no penetrating hole (through hole 11) are provided, and the perimeter of the holes in the board (printed wiring board 1) on the side opposite to the side where the terminals are formed is subjected to treatment for reflection of near-infrared rays.

A CCD sensor or a CMOS sensor used for a solid imaging device is sensitive to intense light, and the solid imaging device has a filter sensitive to heat. For this reason, the solid imaging device cannot be heated directly. The present invention, in which the rear surface of the printed wiring board 1 is heated, can be suitable for soldering of such a solid imaging device.

[1] A method for manufacturing a camera module structure of the present invention can be expressed as a method in which (i) an optical heating device (halogen lamp 6) and (ii) a board (printed wiring board 1) in which holes (through holes 11) are formed in its rear surface at the respective areas corresponding to the terminals 12 to which an electronic component (camera module 2) is soldered, the board having the terminals 12 each of which has no penetrating hole (through hole 11) are provided, and the perimeter of the holes in the board on the side opposite to the side where the terminals are formed (the side where the electronic component is mounted) is subjected to treatment for reflection of light (near-infrared rays) emitted from the light source device.

[2] In the above [1], the optical heating device may be an infrared heating device.

[3] In the above [1], plural sets of combination of the board (printed wiring board 1) and the electronic component (camera module 2) may be soldered at once.

The present invention is not limited to the aforementioned embodiments and is susceptible of various changes within the scope of the accompanying claims.

That is, an embodiment obtained by suitable combinations of technical means varied within the scope of the patent claims set forth below is also included within the technical scope of the present invention.

### INDUSTRIAL APPLICABILITY

The present invention enables soldering by heating from the backside of a wiring board. Therefore, the present invention is applicable to any kinds of solder mounting and can be used in the electronic component industry. For example, the present invention is particularly suitable for soldering performed to join to a wiring board a heat-sensitive electronic component such as a camera module into which an imaging lens used for a digital still camera, a portable phone, or the like and a solid imaging element are integrated.

1. A solder mounting structure in which an electronic component is mounted on a wiring board through solder joint sections, wherein
the wiring board has (i) through holes formed therein that penetrate the wiring board, extending from a mounting surface of the wiring board where the electronic component is mounted to a rear surface thereof, and (ii) terminals formed thereon so as to close front surface apertures which are formed by the through holes in the mounting surface, and
the solder joint sections are provided on the respective terminals.

2. The solder mounting structure according to claim 1, wherein
on the rear surface of the wiring board, reflection layers are provided to reflect light applied to the rear surface of the wiring board, the reflection layers being formed so as not to close rear surface apertures, which are formed by the through holes in the rear surface of the wiring board.

3. The solder mounting structure according to claim 2, wherein
each of the reflection layers is formed around the rear surface aperture.

4. The solder mounting structure according to claim 1, wherein
a reinforcing board is formed so as to close the rear surface apertures.

5. The solder mounting structure according to claim 4, wherein
the reinforcing board has transparence.

6. A method for manufacturing a solder mounting structure according to claim 1, comprising:
a heating step of heating the solder joint sections by way of the terminals by light irradiation to the rear surface of the wiring board.

7. The method according to claim 6, wherein
in the heating step, all the terminals on which the solder joint sections are provided are heated at once.

8. The method according to claim 6, wherein
in the heating step, infrared rays or near-infrared rays are emitted in the light irradiation.

9. The method according to claim 6, wherein
in the heating step, the light irradiation is performed by using a halogen lamp.

10. A manufacturing apparatus of a solder mounting structure according to claim 1, comprising:
a stage, on which the wiring board is placed, having stage through holes formed therein that get through to the through holes of the wiring board; and
a light irradiation section that heats the solder joint sections by light irradiation to the rear surface of the wiring board.

11. The manufacturing apparatus according to claim 10, wherein
on a rear surface of the stage, a first reflecting section is provided to reflect light emitted from the light irradiation section.

12. The manufacturing apparatus according to claim 11, further comprising:
a second reflecting section that reflects light reflected by the first reflecting section toward the stage.

13. An electronic apparatus including a solder mounting structure according to claim 1.

14. A wiring board on which an electronic component is mounted by way of solder joint sections,
the wiring board having (i) through holes formed therein that penetrate the wiring board, extending from a mounting surface of the wiring board where the electronic component is mounted to a rear surface thereof, and (ii) terminals formed thereon so as to close front surface apertures which are formed by the through holes in the mounting surface.
